(19) United States
(12) Patent Application Publication
(10) Pub. No.: US 2020/0136156 A1
(43) Pub. Date: Apr. 30, 2020

(54) THERMOELECTRICALLY ENHANCED FUEL CELLS

(71) Applicant: PHILLIPS 66 COMPANY, Houston, TX (US)

(72) Inventors: Ying Liu, Bartlesville, OK (US); Mingfei Liu, Bartlesville, OK (US)

(73) Assignee: PHILLIPS 66 COMPANY, HOUSTON, TX (US)

(21) Appl. No.: 16/668,614

(22) Filed: Oct. 30, 2019

Related U.S. Application Data
(60) Provisional application No. 62/752,581, filed on Oct. 30, 2018.

(51) Int. Cl. H01M 8/04007; H01L 35/22; H01L 35/32

(52) U.S. Cl. CPC H01M 8/04067; H01M 2008/1293; H01L 35/32; H01L 35/22

(57) ABSTRACT

A fuel cell system comprising an anode, an electrolyte supported by the anode; and a cathode supported by the electrolyte. A primary thermoelectric ceramic is in contact with the cathode positioned on the opposing side of the electrolyte. An optional secondary thermoelectric ceramic is in contact with the anode positioned on the opposite side of the electrolyte. In this embodiment air and fuel gas surround the fuel cell at a temperature lower than the operational internal temperature of the fuel cell and both the primary thermoelectric ceramic and the optional secondary thermoelectric ceramic are capable of converting the temperature difference between the fuel cell and both the air and the fuel gas into an additional output voltage.

### CROSS-REFERENCE TO RELATED APPLICATIONS

This application is a non-provisional application which claims the benefit of and priority to U.S. Provisional Application Ser. No. 62/752,581 filed Oct. 30, 2018, titled “Thermoelectrically Enhanced Fuel Cells,” which is hereby incorporated by reference in its entirety.

### STATEMENT REGARDING FEDERALLY SPONSORED RESEARCH OR DEVELOPMENT

None.

### FIELD OF THE INVENTION

This invention relates to thermoelectrically enhanced fuel cells.

### BACKGROUND OF THE INVENTION

In general, fuel cells are electrochemical devices in which the chemical energy of fuels is converted directly into electrical energy via electrochemical reactions. Considering the basic principle thereof, the fuel cells are adapted to produce electricity by oxidation of hydrogen obtained by modifying fossil fuels, such as petroleum or natural gas, or pure hydrogen. During the oxidation of hydrogen, heat and water vapor are generated as byproducts. There are different types of fuel cells such as phosphoric acid fuel cells, alkaline fuel cells, molten carbonate fuel cells, solid oxide fuel cells, and proton exchange membrane fuel cells.

However, fuel cells are associated with some significant drawbacks despite their high energy conversion efficiency. There exist substantial temperature gradients within solid oxide fuel cells and fuel cell stacks. There are opportunities for generating additional electricity by taking advantage of such temperature gradients.

There exists a need for a method of utilizing the waste heat or temperature gradient of a fuel cell.

### BRIEF SUMMARY OF THE DISCLOSURE

A fuel cell system comprising an anode, an electrolyte supported by the anode, and a cathode supported by the electrolyte. A primary thermoelectric ceramic is in contact with the cathode positioned on the opposing side of the electrolyte. An optional secondary thermoelectric ceramic is in contact with the anode positioned on the opposite side of the electrolyte. In this embodiment air and fuel gas surround the fuel cell at a temperature lower than the operational internal temperature of the fuel cell and both the primary thermoelectric ceramic and the optional secondary thermoelectric ceramic are capable of converting the temperature difference between the fuel cell and both the air and the fuel gas into an additional output voltage and power.

A solid oxide fuel cell system comprising an anode, an electrolyte supported by the anode, and a cathode supported by the electrolyte. A primary thermoelectric ceramic p-type conductor is in contact with the cathode positioned on the opposing side of the electrolyte. A secondary thermoelectric ceramic n-type conductor is in contact with the anode positioned on the opposite side of the electrolyte. In this embodiment air and a fuel gas surround the fuel cell at a temperature lower than the operational internal temperature of the solid oxide fuel cell and both the primary thermoelectric ceramic and the optional secondary thermoelectric ceramic are capable of converting the temperature difference between the solid oxide fuel cell and both the air and the fuel gas into an additional output voltage and power.

### BRIEF DESCRIPTION OF THE DRAWINGS

A more complete understanding of the present invention and benefits thereof may be acquired by referring to the follow description taken in conjunction with the accompanying drawings in which:

FIG. 1 depicts a schematic block diagram of a conventional fuel cell

FIG. 2 depicts one embodiment of the novel fuel cell system.

FIG. 3 depicts one embodiment of the novel solid oxide fuel cell.

FIG. 4 depicts a temperature gradient as it relates to thermoelectric voltage.

FIG. 5 depicts voltage compared to current density of a conventional fuel cell and one with La_{0.9}Sr_{0.1}FeO₃.

FIG. 6 depicts voltage compared to current density of a conventional fuel cell and one with La_{0.9}Sr_{0.1}FeO₃.

FIG. 7 depicts open circuit voltage of the fuel cell with and without the thermoelectric ceramic.

FIG. 8 depicts power density of the fuel cell with and without the thermoelectric ceramic.

FIG. 9 depicts x-ray diffraction pattern of a thermoelectric ceramic.

FIG. 10 depicts electrical conductivities of thermoelectric ceramics

FIG. 11 depicts open circuit voltage of the fuel cell with and without the thermoelectric ceramic.

FIG. 12 depicts power density of the fuel cell with and without the thermoelectric ceramic.

### DETAILED DESCRIPTION

Turning now to the detailed description of the preferred arrangement or arrangements of the present invention, it should be understood that the inventive features and concepts may be manifested in other arrangements and that the scope of the invention is not limited to the embodiments described or illustrated. The scope of the invention is intended only to be limited by the scope of the claims that follow.

Conventional fuel cells, such as polymer electrolyte membrane fuel cells, direct methanol fuel cells, alkaline fuel cells, phosphoric acid fuel cells, molten carbonate, solid oxide fuel cells, or reversible fuel cells, all create heat during operation.

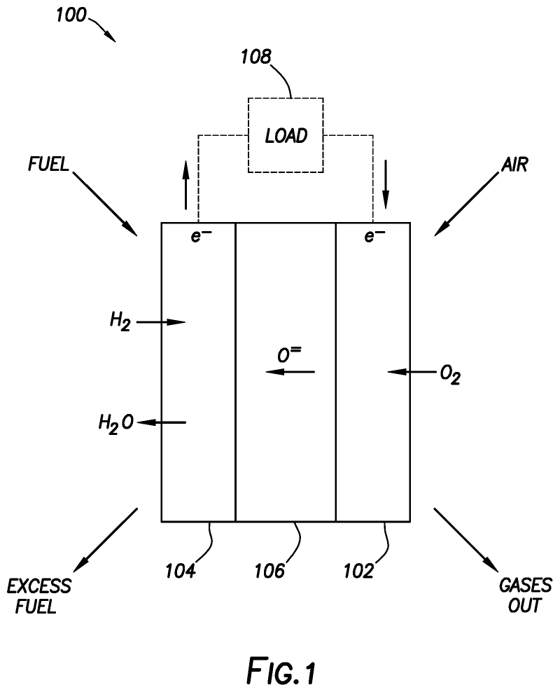

FIG. 1 depicts a schematic block diagram of a conventional fuel cell 100. The illustrated fuel cell 100 includes a cathode 102, an anode 104, and an electrolyte 106. In general, the cathode 102 extracts oxygen (O₂) from an input oxidant (e.g., ambient air) and reduces the oxygen into oxygen ions. The remaining gases are exhausted from the fuel cell 100. The electrolyte 106 diffuses the oxygen ions from the cathode 102 to the anode 104. The anode 104 uses the oxygen ions to oxidize hydrogen (H₂) from the input fuel (i.e., combine the hydrogen and the oxygen ions). The oxidation of the hydrogen forms water (H₂O) and free electrons (e⁻). The water exits the anode 104 with any excess fuel. The free electrons can travel through an external circuit (shown dashed with a load 108) between the anode 104 and the cathode 102. When combined with other fuel cells 100 within a fuel cell stack, the power generation capabilities of all of the solid oxide fuel cells 100 can be combined to output more power.

The present embodiment describes a fuel cell system comprising an anode, an electrolyte supported by the anode, and a cathode supported by the electrolyte. A primary thermoelectric ceramic is in contact with the cathode positioned on the opposing side of the electrolyte. An optional secondary thermoelectric ceramic is in contact with the anode positioned on the opposite side of the electrolyte. In this embodiment an air and a fuel gas surround the fuel cell at a temperature lower than the operational internal temperature of the fuel cell and both the primary thermoelectric ceramic and the optional secondary thermoelectric ceramic are capable of converting the temperature difference between the fuel cell and both the air and the fuel gas into an additional output voltage.

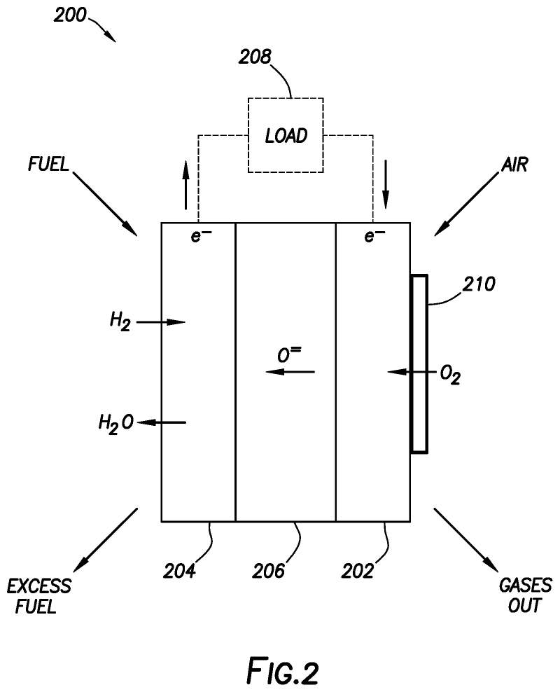

FIG. 2 depicts one embodiment of the novel fuel cell system. The novel fuel cell 200 includes a cathode 202, an anode 204, an electrolyte 206, and a primary thermoelectric ceramic 210. The cathode materials chosen for the fuel cell can be any conventionally known cathode capable of converting oxygen (O₂) from an input oxidant (e.g., ambient air) and reduces the oxygen into oxygen ions. Examples of the cathode material can be perovskite materials, lanthanum manganite materials, lanthanum cobaltite and ferrite materials, ferro-cobaltite materials, and nickelate materials. Other more specific examples of cathode materials can be Pr_{0.5}Sr_{0.5}FeO_{3-δ}; Sr_{0.9}Ce_{0.1}Fe_{0.8}Ni_{0.2}O_{3-δ}; Sr_{0.8}Ce_{0.1}Fe_{0.7}Co_{0.3}O_{3-δ}; LaNi_{0.6}Fe_{0.4}O_{3-δ}; Pr_{0.8}Sr_{0.2}Co_{0.2}Fe_{0.8}O_{3-δ}; Pr_{0.7}Sr_{0.3}Co_{0.2}Mn_{0.8}O_{3-δ}; Pr_{0.8}Sr_{0.2}FeO_{3-δ}; Pr_{0.6}Sr_{0.4}Co_{0.8}Fe_{0.2}O_{3-δ}; Pr_{0.4}Sr_{0.6}Co_{0.8}Fe_{0.2}O_{3-δ}; Pr_{0.7}Sr_{0.3}Co_{0.9}Cu_{0.1}O_{3-δ}; Ba_{0.5}Sr_{0.5}Co_{0.8}Fe_{0.2}O_{3-δ}; Sm_{0.5}Sr_{0.5}CoO_{3-δ}; and LaNi_{0.6}Fe_{0.4}O_{3-δ}. In one embodiment the cathode material is a mixture of gadolinium-doped ceria (Ce_{0.9}Gd_{0.1}O₂) and lanthanum strontium cobalt ferrite (La_{0.6}Sr_{0.4}Co_{0.2}Fe_{0.8}O₃) or a mixture of gadolinium-doped ceria (Ce_{0.9}Gd_{0.1}O₂) and samarium strontium cobaltite, Sm_{0.5}Sr_{0.5}CoO₃.

The electrolyte 206 diffuses the oxygen ions from the cathode 202 to the anode 204. Examples of the electrolyte materials that can be used include yittria-stabilized zirconia, scandium-stabilized zirconia, gadolinium doped ceria, or lanthanum strontium magnesium gallate. Other more specific examples of electrolyte materials can be (ZrO₂)_{0.92}(Y₂O₃)_{0.08}, Ce_{0.9}Gd_{0.1}O₂, Ce_{0.9}Sm_{0.2}O₂, La_{0.8}Sr_{0.2}Ga_{0.8}Mg_{0.2}O₃, BaZr_{0.1}Ce_{0.7}Y_{0.1}Yb_{0.1}O₃.

The anode 204 uses the oxygen ions to oxidize hydrogen (H₂) from the input fuel (i.e., combine the hydrogen and the oxygen ions). Examples of anode material include mixtures of NiO, yttria-stabilized zirconia, gadolinium-doped ceria, CuO, CoO and FeO. Other more specific examples of anode materials can be a mixture of 50 wt. % NiO and 50 wt. % yttria-stabilized zirconia or a mixture of 50 wt. % NiO and 50 wt. % gadolinium-doped ceria.

The oxidation of the hydrogen forms water (H₂O) and free electrons (e⁻). The water exits the anode 204 with any excess fuel. The free electrons can travel through a circuit (shown dashed with a load 208) between the anode 204 and the cathode 202. A primary thermoelectric ceramic 210 is shown in contact with the cathode positioned on the opposing side of the electrolyte. It is envisioned that the primary thermoelectric ceramic should have good thermoelectric properties, the materials should have high values of Seebeck coefficients (ΔV/ΔT), high electrical conductivities, and low thermal conductivities. Additionally, the primary thermoelectric ceramic should be a p-type conductor and stable in oxygen at fuel cell operating temperatures. Examples of the primary thermoelectric ceramic include: La_{0.9}Sr_{0.1}FeO₃, LaCoO₃, La_{0.8}Sr_{0.2}CoO₃, LaCo_{0.2}Fe_{0.8}O₃, La_{0.8}Sr_{0.2}Co_{0.2}Fe_{0.8}, La_{0.7}Ca_{0.3}CrO₃, LaFe_{0.7}Ni_{0.3}O₃, Ca_{2.5}Tb_{0.5}Co₄O₉, Ca₃Co₄O₉, Ca₂Co₂O₅, Ca₃Co₂O₆, Ca₃Co₃O₉, Ca_{2.9}Nd_{0.1}Co₄O₉, CaCo_{3.9}Cu_{0.1}O₉, CaMnO₃, Ca_{2.9}Nd_{0.1}MnO₃, SrTiO₃, Si_{0.7}Ge_{0.22}, Ca_{0.9}Yb_{0.1}MnO₃, Ca_{2.7}Bi_{0.3}Co₄O₉, Na₂Co₂O₄, SrTi_{0.9}Ta_{0.1}O₃, Sr_{0.925}La_{0.15}TiO₃, Sr_{0.9}Dy_{0.1}TiO₃.

When combined with other fuel cells 200 within a fuel cell stack, the power generation capabilities of all of the solid oxide fuel cells 200 can be combined to output more power.

In yet another embodiment, the fuel cell system can describe a solid oxide fuel system wherein the solid oxide fuel cell system comprises an anode, an electrolyte supported by the anode, and a cathode supported by the electrolyte. A primary thermoelectric ceramic p-type conductor is in contact with the cathode positioned on the opposing side of the electrolyte. A secondary thermoelectric ceramic n-type conductor is in contact with the anode positioned on the opposite side of the electrolyte. In this embodiment an air and a fuel gas surround the fuel cell at a temperature lower than the operational internal temperature of the solid oxide fuel cell and both the primary thermoelectric ceramic and the optional secondary thermoelectric ceramic are capable of converting the temperature difference between the solid oxide fuel cell and both the air and the fuel gas into an additional output voltage.

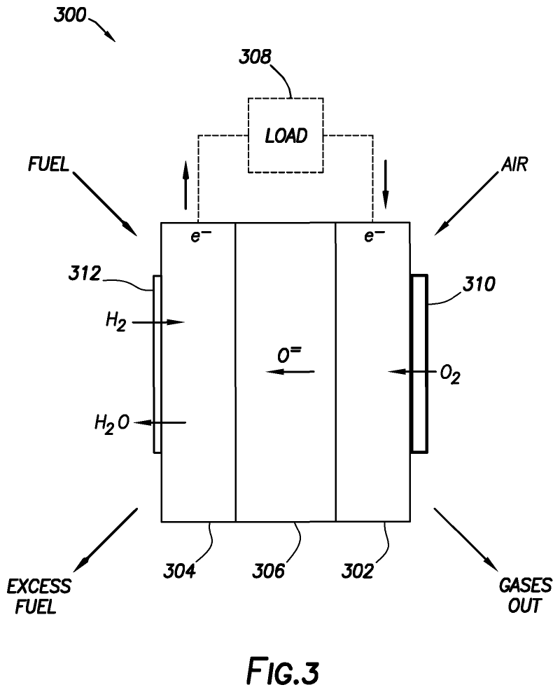

FIG. 3 depicts a novel embodiment of the solid oxide fuel cell 300. The illustrated fuel cell 300 includes a cathode 302, an anode 304, and an electrolyte 306. A primary thermoelectric ceramic 310 is shown in contact with the cathode positioned on the opposing side of the electrolyte. A secondary thermoelectric ceramic 312 in contact with the anode positioned on the opposite side of the electrolyte. In general, the cathode 302 extracts oxygen (O₂) from an input oxidant (e.g., ambient air) and reduces the oxygen into oxygen ions. The remaining gases are exhausted from the fuel cell 300. The electrolyte 306 diffuses the oxygen ions from the cathode 302 to the anode 304. The anode 104 uses the oxygen ions to oxidize hydrogen (H₂) from the input fuel (i.e., combine the hydrogen and the oxygen ions). The oxidation of the hydrogen forms water (H₂O) and free electrons (e⁻). The water exits the anode 304 with any excess fuel. The free electrons can travel through a circuit (shown dashed with a load 308) between the anode 304 and the cathode 302. It is envisioned that the secondary thermoelectric ceramic should have good thermoelectric properties, the materials should have high values of Seebeck coefficients (ΔV/ΔT), high electrical conductivities, and low thermal conductivities. Additionally, the secondary thermoelectric ceramic should be a n-type conductor and stable in oxygen at fuel cell operating temperatures. Examples of the secondary thermoelectric ceramic include: La_{0.9}Sr_{0.1}FeO₃, LaCoO₃, La_{0.8}Sr_{0.2}CoO₃, LaCo_{0.2}Fe_{0.8}O₃, La_{0.8}Sr_{0.2}Co_{0.2}Fe_{0.8}, La_{0.7}Ca_{0.3}CrO₃, LaFe_{0.7}Ni_{0.3}O₃, Ca_{2.5}Tb_{0.5}Co₄O₉, Ca₃Co₄O₉, Ca₂Co₂O₅, Ca₃Co₂O₆, Ca₃Co₃O₉, Ca_{2.9}Nd_{0.1}Co₄O₉, CaCo_{3.9}Cu_{0.1}O₉, CaMnO₃, Ca_{2.9}Nd_{0.1}MnO₃, SrTiO₃, Si_{0.7}Ge_{0.22}, Ca_{0.9}Yb_{0.1}MnO₃, Ca_{2.7}Bi_{0.3}Co₄O₉, Na₂Co₂O₄, SrTi_{0.9}Ta_{0.1}O₃, Sr_{0.925}La_{0.15}TiO₃, Sr_{0.9}Dy_{0.1}TiO₃.

When combined with other fuel cells 300 within a fuel cell stack, the power generation capabilities of all of the solid oxide fuel cells 300 can be combined to output more power.

The additional output voltage from the primary thermoelectric ceramic and the secondary thermoelectric ceramic would be partially dependent upon the temperature difference between the operation internal temperature of the fuel cell and the temperature of both the air and the fuel gas. While not limited to this range it is anticipated that the additional output voltage would range from about 5 mV to about 150 mV. It is also envisioned that the temperature difference between the operation internal temperature of the fuel cell and the temperature of the air and fuel gas mixture range from about 5° C. to about 250° C.

The thickness of the primary thermoelectric ceramic and the secondary thermoelectric ceramic independently range from about 30 μm to about 5 mm.

The following examples of certain embodiments of the invention are given. Each example is provided by way of explanation of the invention, one of many embodiments of the invention, and the following examples should not be read to limit, or define, the scope of the invention.

### Example 1

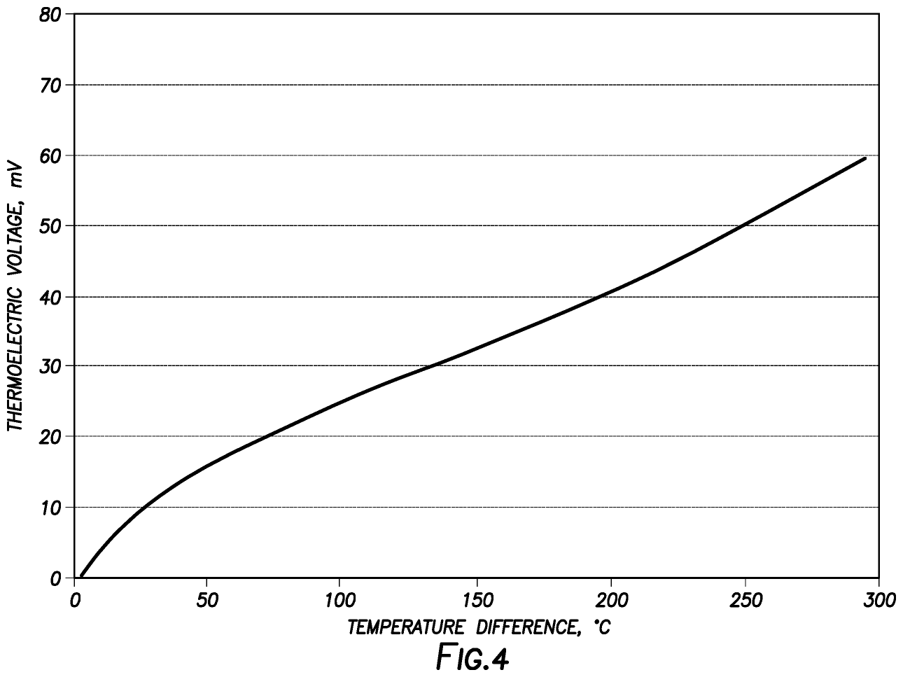

La_{0.9}Sr_{0.1}FeO₃ was tested as a thermoelectric material. One end of a 20 mm long bar was held in a furnace with a set temperature of 700° C. while the other end was cooled with ambient air to create a temperature gradient. The results of the temperature gradient are shown in FIG. 4.

### Example 2

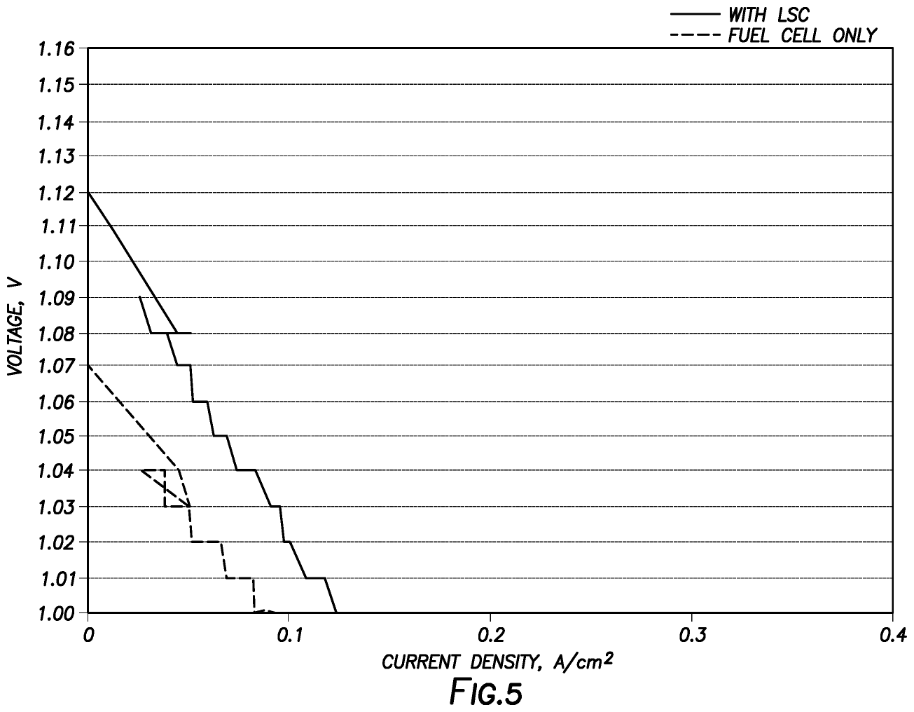

La_{0.9}Sr_{0.1}FeO₃ was added to a fuel cell (the fuel cell has a 30 μm La_{0.6}Sr_{0.4}Co_{0.2}Fe_{0.8}O₃—Ce_{0.9}Gd_{0.1}O₂ cathode, a 10 μm (ZrO₂)_{0.92}(Y₂O₃)_{0.8} electrolyte, and a 300 μm NiO—(ZrO₂)_{0.92}(Y₂O₃)_{0.08} anode with ceramic contact paste. The fuel cell was kept at 700° C. while the top end of the La_{0.9}Sr_{0.1}FeO₃ bar cooled to 550° C. by blowing ambient air. The fuel cell showed an open circuit voltage of 1.066 V while the voltage measured at the end of the La_{0.9}Sr_{0.1}FeO₃ bar was 1.119V, an improvement of 53 mV. These voltages are shown in FIG. 5.

### Example 3

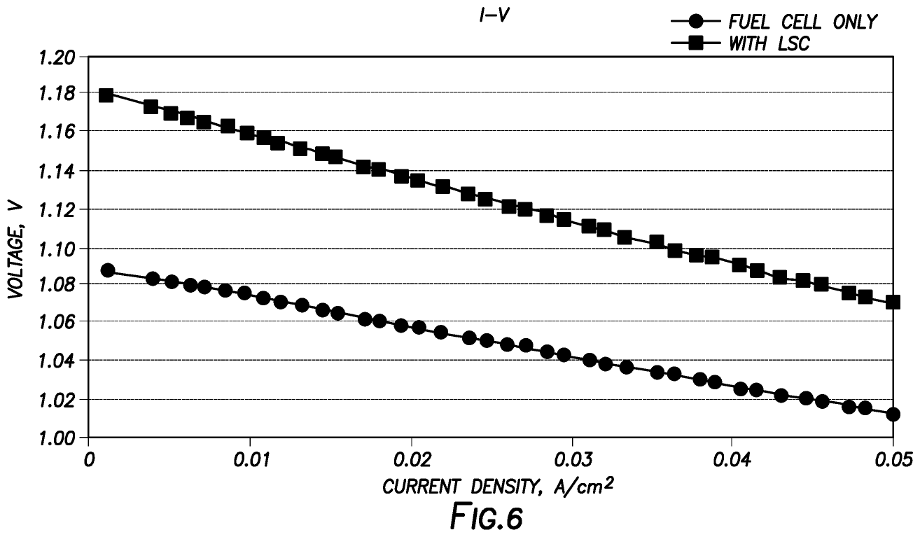

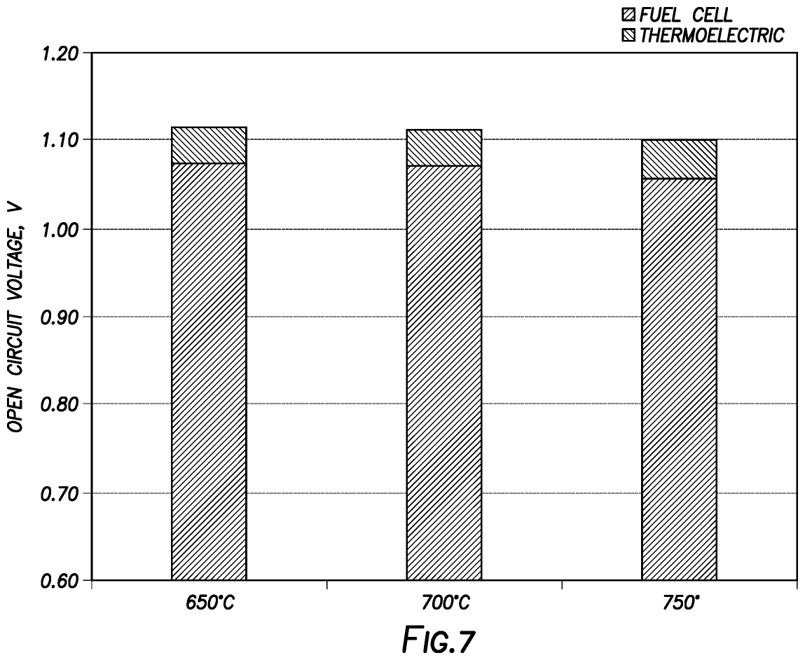

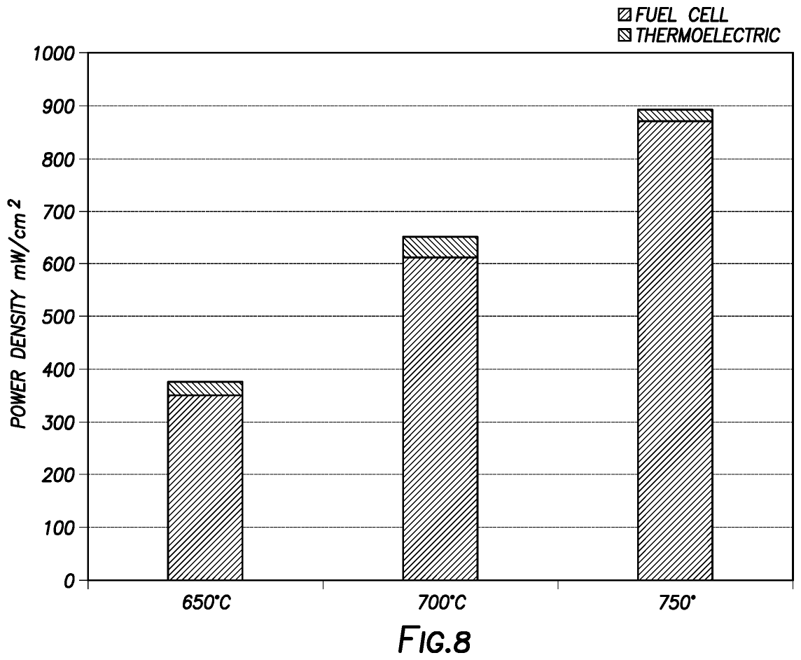

La_{0.9}Sr_{0.1}FeO₃ was added to a fuel cell (the fuel cell has a 30 μm Sm_{0.5}Sr_{0.5}CoO₃—Ce_{0.9}Gd_{0.1}O₂ cathode, a 10 μm (ZrO₂)_{0.92}(Y₂O₃)_{0.08} electrolyte, and a 300 μm NiO—(ZrO₂)_{0.92}(Y₂O₃)_{0.08} anode) with ceramic contact paste. The fuel cell was kept at 700° C. while the top end of the La_{0.9}Sr_{0.1}FeO₃ bar cooled to 480° C. by blowing ambient air. The fuel cell showed an open circuit voltage of 1.09V while the voltage measured at the end of the La_{0.9}Sr_{0.1}FeO₃ bar was 1.18V, an improvement of 90 mV. The voltages are shown in FIG. 6. Furthermore, when the cell temperatures were kept at 650, 700, and 750° C. while the top end of the La_{0.9}Sr_{0.1}FeO₃ bar cooled to 514, 558, and 603° C. by blowing ambient air, the fuel cell showed open circuit voltages of 1.076, 1.072, 1.059 V while the voltages measured at the end of the La_{0.9}Sr_{0.1}FeO₃ bar were 1.114, 1.113, and 1.102 V, respectively. When current was drawn out of the device, extra 7.5, 6.0 and 2.3% power was produced by the La_{0.9}Sr_{0.1}FeO₃ bar. The voltages and power outputs are shown in FIG. 7 and FIG. 8 respectfully.

### Example 4

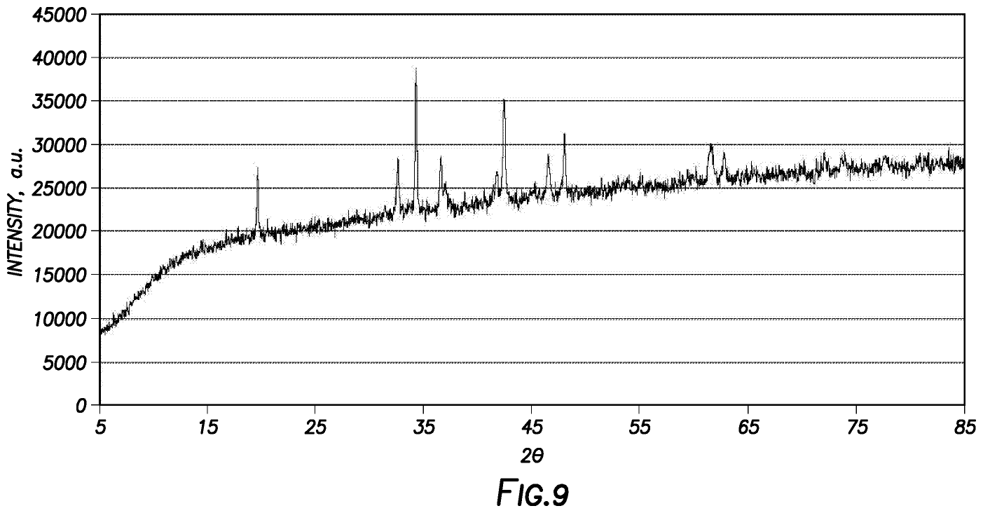

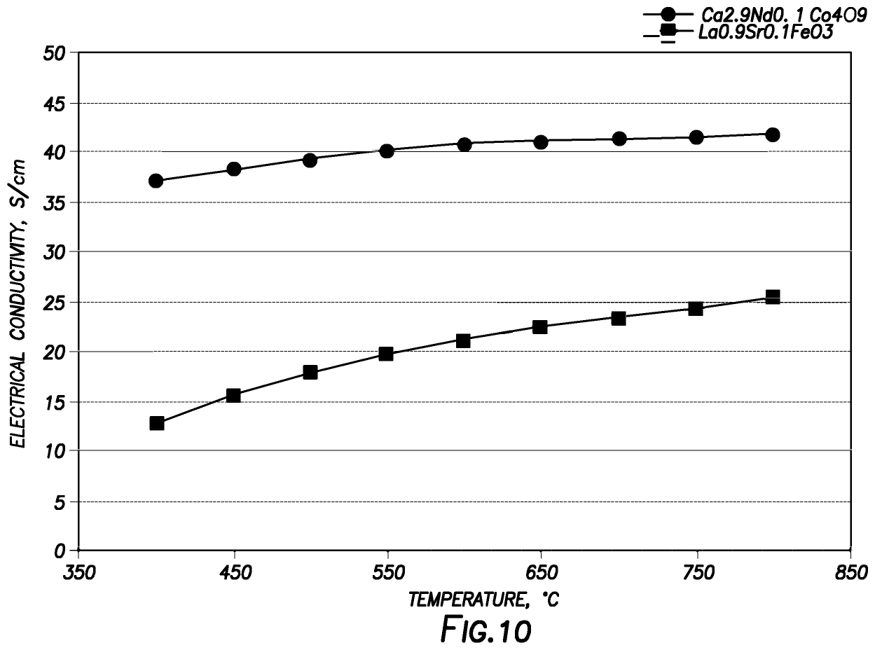

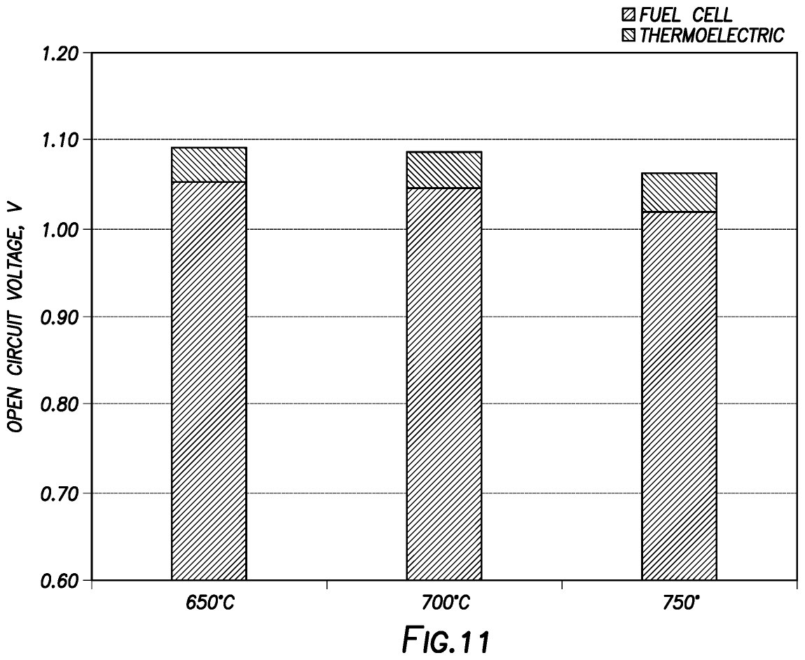

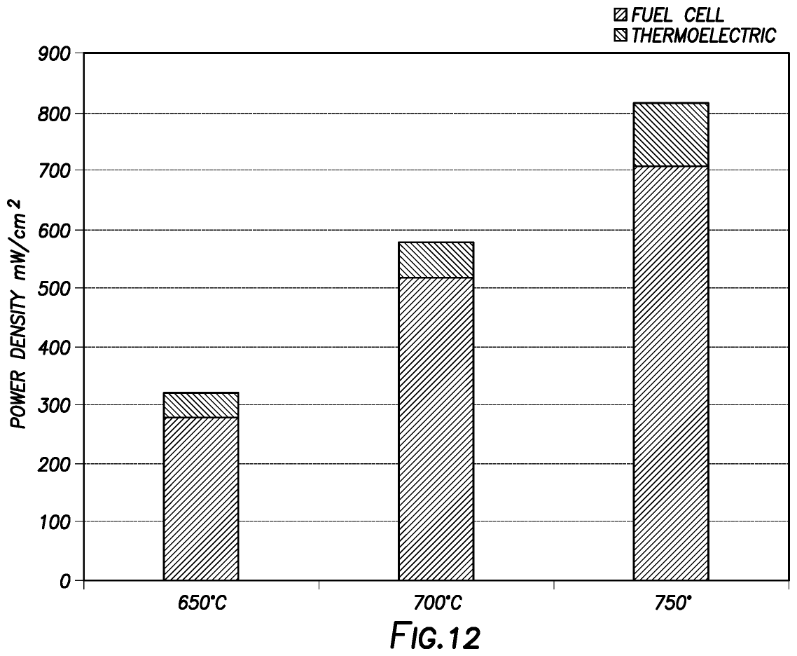

A p-type thermoelectric ceramic, Ca_{2.9}Nb_{0.1}Co₄O₉ was developed. The material has a perovskite structure as shown in its X-ray diffraction pattern (FIG. 9). The electrical conductivities of this new material are twice as high as those of La_{0.9}Sr_{0.1}FeO₃ at 400 to 800° C. (FIG. 10). Ca_{2.9}Nb_{0.1}Co₄ was added to a fuel cell (the fuel cell has a 30 μm Sm_{0.5}Sr_{0.5}CoO₃—Ce_{0.9}Gd_{0.1}O₂ cathode, a 10 μm (ZrO₂)_{0.92}(Y₂O₃)_{0.08} electrolyte, and a 300 μm NiO—(ZrO₂)_{0.92}(Y₂O₃)_{0.08} and) with ceramic contact paste. The fuel cell was kept at 650 to 700° C. while the top end of the Ca_{2.9}Nb_{0.1}Co₄ bar cooled to 150° C. lower by blowing ambient air. The fuel cell showed open circuit voltages of 1.055, 1.408, and 1.020 V, while the new thermoelectric material added extra 38, 42, and 45 mV at these temperatures, respectively (FIG. 11). When current was applied, the fuel cell produced power densities of 279, 517, and 712 mW/cm² at 650, 700, and 750° C. while the thermoelectric material generated additional 14.5, 11.6, and 14.7% power at these temperatures (FIG. 12).

In closing, it should be noted that the discussion of any reference is not an admission that it is prior art to the present invention, especially any reference that may have a publication date after the priority date of this application. At the same time, each and every claim below is hereby incorporated into this detailed description or specification as an additional embodiment of the present invention.

Although the systems and processes described herein have been described in detail, it should be understood that various changes, substitutions, and alterations can be made without departing from the spirit and scope of the invention as defined by the following claims. Those skilled in the art may be able to study the preferred embodiments and identify other ways to practice the invention that are not exactly as described herein. It is the intent of the inventors that variations and equivalents of the invention are within the scope of the claims while the description, abstract and drawings are not to be used to limit the scope of the invention. The invention is specifically intended to be as broad as the claims below and their equivalents.

1. A fuel cell system comprising:
an anode;
an electrolyte supported by the anode;
a cathode supported by the electrolyte;
a primary thermoelectric ceramic in contact with the cathode positioned on the opposing side of the electrolyte; and
an optional secondary thermoelectric ceramic in contact with the anode positioned on the opposite side of the electrolyte,
wherein air and fuel gas surround the fuel cell at a temperature lower than the operational internal temperature of the fuel cell and both the primary thermoelectric ceramic and the optional secondary thermoelectric ceramic are capable of converting the temperature difference between the fuel cell and both the air and the fuel gas into an additional output voltage.

2. The fuel cell system of claim 1, wherein the fuel cell is a solid oxide fuel cell.

3. The fuel cell system of claim 1, wherein the additional output voltage ranges from about 5 mV to about 150 mV.

4. The fuel cell of claim 1, wherein the primary thermoelectric ceramic and the optional secondary thermoelectric ceramic are independently selected from the group consisting of: La_{0.9}Sr_{0.1}FeO₃, LaCoO₃, La_{0.8}Sr_{0.2}CoO₃, LaCo_{0.2}Fe_{0.8}O₃, La_{0.8}Sr_{0.2}Co_{0.2}Fe_{0.8}, La_{0.7}Ca_{0.3}CrO₃, LaFe_{0.7}Ni_{0.3}O₃, Ca_{2.5}Tb_{0.5}Co₄O₉, Ca₃Co₄O₉, Ca₂Co₂O₅, Ca₃Co₂O₆, Ca₃Co₃O₉, Ca_{2.9}Nd_{0.1}Co₄O₉, CaCo_{3.9}Cu_{0.1}O₉, CaMnO₃, Ca_{2.9}Nd_{0.1}MnO₃, SrTiO₃, Si_{0.7}Ge_{0.22}, Ca_{0.9}Yb_{0.1}MnO₃, Ca_{2.7}Bi_{0.3}Co₄O₉, Na₂Co₂O₄, SrTi_{0.9}Ta_{0.1}O₃, Sr_{0.925}La_{0.15}TiO₃, Sr_{0.9}Dy_{0.1}TiO₃, and combinations thereof.

5. The fuel cell of claim 1, wherein the temperature difference between operational internal temperature of the solid oxide fuel cell and the both the air and the fuel gas ranges from about 5° C. to about 250° C.,

6. The fuel cell of claim 1, wherein the thickness of the primary thermoelectric ceramic and the optional secondary thermoelectric ceramic independently range from about 30 μm to about 5 mm.

7. The fuel cell of claim 1, wherein the primary thermoelectric ceramic is a p-type conductor.

8. The fuel cell of claim 1, wherein the optional secondary thermoelectric ceramic is a n-type conductor.

9. A solid oxide fuel cell system comprising:
an anode;
an electrolyte supported by the anode;
a cathode supported by the electrolyte;
a primary thermoelectric ceramic p-type conductor in contact with the cathode positioned on the opposing side of the electrolyte; and
a secondary thermoelectric ceramic n-type conductor in contact with the anode positioned on the opposite side of the electrolyte,
wherein air and fuel gas surround the solid oxide fuel cell at a temperature lower than the operational internal temperature of the solid oxide fuel cell and both the primary thermoelectric ceramic and the optional secondary thermoelectric ceramic are capable of converting the temperature difference between the solid oxide fuel cell and both the air and the fuel gas into an additional output voltage.
